(19) United States
(12) Patent Application Publication
(10) Pub. No.: US 2011/0024896 A1
(43) Pub. Date: Feb. 3, 2011

(54) POWER SEMICONDUCTOR DEVICE

(75) Inventors: Tetsujiro Tsunoda, Tokyo (JP); Takuya Hamaguchi, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, Tokyo (JP)

(21) Appl. No.: 12/934,127

(22) PCT Filed: Jul. 7, 2008
(86) PCT No.: PCT/JP2008/062281

§ 371 Date: Sep. 23, 2010

(51) Int. Cl. H01L 23/34

(52) U.S. Cl. 257/707; 257/E23.08

(57) ABSTRACT

A power semiconductor device that can reduce the mounting area thereof will be provided. A first metal plate is connected to a first power terminal of a power chip. A second metal plate facing the first metal plate is connected to a second power terminal of the power chip. An insulating cover coats the power chip from outside of the first and second metal plates. An exterior signal terminal connected to the signal terminal of the power chip is derived from an upper surface of the insulating cover. The first and second metal plate respectively includes first and second exterior electric power terminals derived from a lower surface of the insulating cover. The first and second exterior electric power terminals are bent to opposite directions. In a bending direction of the first exterior electric power terminal or the second exterior electric power terminal, the second exterior electric power terminal is not present on opposite side of the first exterior electric power terminal across the insulating cover, and the first exterior electric power terminal is not present on opposite side of the second exterior electric power terminal across the insulating cover.

### BACKGROUND OF THE INVENTION

1. Field of the Invention

The present invention relates to a power semiconductor device equipped with power chips, such as IGBT (Insulated Gate Bipolar Transistor) chips, more particularly to a power semiconductor device that can reduce the mounting area thereof.

2. Background Art

A power semiconductor device for supplying electric power to a power chip and dissipating heat from the power chip by two metal plates sandwiching the power chip has been proposed (for example, refer to Patent Document 1 and Patent Document 2).

### Patent Document 1: Japanese Patent Laid-Open No. 2004-6967

### Patent Document 2: Japanese Patent Laid-Open No. 2006-190972

### DISCLOSURE OF THE INVENTION

### Problem to be Solved by the Invention

A power system is constituted by connecting a plurality of power semiconductor devices. At this time, it is required to reduce the mounting area of the power semiconductor devices to constitute a small power system.

The present invention has been implemented to solve the above described problems and it is an object of the present invention to provide a power semiconductor device that can reduce the mounting area thereof.

### MEANS FOR SOLVING THE PROBLEMS

The present invention is a power semiconductor device comprising: a power chip wherein a first power terminal and a signal terminal are formed on a first major surface and a second power terminal is formed on a second major surface facing the first major surface; a first metal plate connected to the first power terminal of the power chip; a second metal plate arranged so as to face the first metal plate and connected to the second power terminal of the power chip; an insulating cover coating the power chip from outside of the first and second metal plates; and an exterior signal terminal connected to the signal terminal of the power chip and derived from an upper surface of the insulating cover, the first metal plate includes a first exterior electric power terminal derived from a lower surface of the insulating cover, the second metal plate includes a second exterior electric power terminal derived from a lower surface of the insulating cover, the first and second exterior electric power terminals are bent to opposite directions, in a bending direction of the first exterior electric power terminal or the second exterior electric power terminal, the second exterior electric power terminal is not present on opposite side of the first exterior electric power terminal across the insulating cover, and the first exterior electric power terminal is not present on opposite side of the second exterior electric power terminal across the insulating cover.

### EFFECT OF THE INVENTION

The present invention makes it possible to reduce the mounting area thereof. Therefore, a small power system can be constituted.

### BRIEF DESCRIPTION OF THE DRAWINGS

FIG. 1 is a perspective view showing a power semiconductor device according to the first embodiment of the present invention.

FIG. 2 is a plan view showing a power semiconductor device according to the first embodiment of the present invention.

FIG. 3 is a perspective view showing the interior of the power semiconductor device shown in FIG. 1.

FIG. 4 is a sectional view taken along the line A-A′ in FIG. 3.

FIG. 5 is an enlarged sectional view showing the major parts of FIG. 4.

FIG. 6 is a circuit diagram of the power semiconductor device shown in FIG. 1.

FIG. 7 is a perspective view showing an example of the state wherein the power semiconductor device shown in FIG. 1 is mounted on a heat sink.

FIG. 8 is a perspective view showing another example of the state wherein the power semiconductor device shown in FIG. 1 is mounted on a heat sink.

FIG. 9 is a plan view showing an example of the layout of the power semiconductor device shown in FIG. 1.

FIG. 10 is a plan view showing another example of the layout of the power semiconductor device shown in FIG. 1.

FIG. 11 is a sectional view showing the interior of a power semiconductor device according to the second embodiment of the present invention.

FIG. 12 is a sectional view showing the interior of a power semiconductor device according to the third embodiment of the present invention.

FIG. 13 is a sectional view showing the interior of a power semiconductor device according to the fourth embodiment of the present invention.

FIG. 14 is a sectional view showing the interior of a power semiconductor device according to the fifth embodiment of the present invention.

FIG. 15 is a sectional view taken along the line B-B′ in FIG. 14.

FIG. 16 is a sectional view showing the interior of a power semiconductor device according to the sixth embodiment of the present invention.

FIG. 17 is a sectional view showing the interior of a power semiconductor device according to the seventh embodiment of the present invention.

FIG. 18 is a sectional view showing the interior of a power semiconductor device according to the eighth embodiment of the present invention.

### DESCRIPTION OF REFERENCE NUMERALS

10 power semiconductor device

12 insulating cover

16 exterior signal terminal

18 first exterior electric power terminal

20 second exterior electric power terminal

26 IGBT chip (power chip)

26a emitter (first power terminal)

26b gate (signal terminal)

26c collector (second power terminal)

30 first metal plate

30a, 30b convex portion

30c, 30d elastic portion

32 second metal plate

58, 60, 66, 68 stress-relaxing metal plate

74, 84 insulating guide

The embodiments of the present invention will be described referring to the drawings. In the drawings, the same or corresponding parts will be denoted by the same symbols, and the description thereof will be simplified or omitted.

### FIRST EMBODIMENT

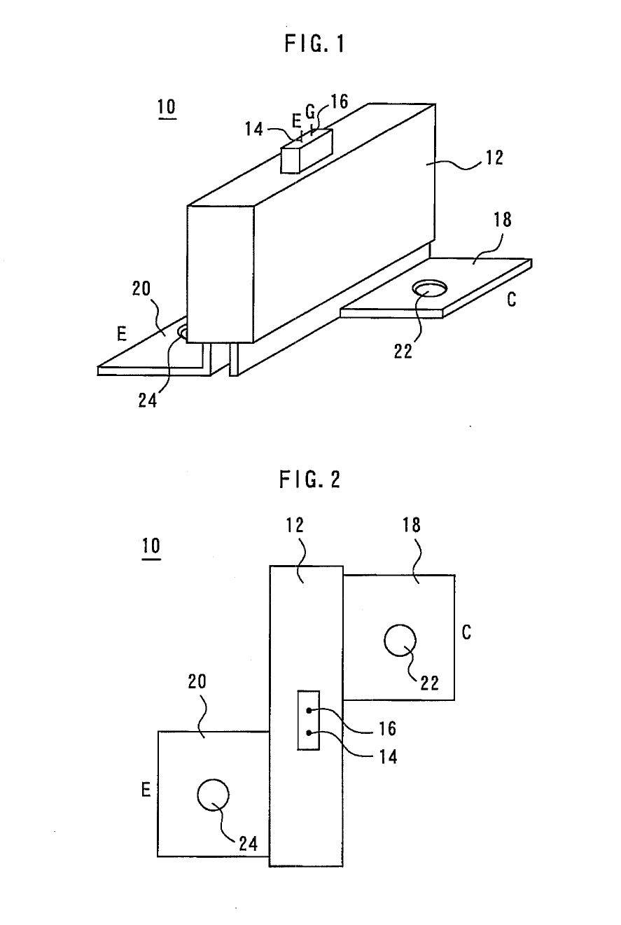

FIG. 1 is a perspective view showing a power semiconductor device according to the first embodiment of the present invention; and FIG. 2 is a plan view thereof. Exterior signal terminals 14 and 16 are derived from the upper surface of an insulating cover 12 of a power semiconductor device 10, and first and second exterior electric power terminals 18 and 20 are derived from the lower surface of the insulating cover 12. The first and second exterior electric power terminals 18 and 20 are bent to opposite directions. In the bending direction of the first exterior electric power terminal 18 or the second exterior electric power terminal 20, the second exterior electric power terminal 20 is not present on the opposite side of the first exterior electric power terminal 18 across the insulating cover 12; and the first exterior electric power terminal 18 is not present on the opposite side of the second exterior electric power terminal 20 across the insulating cover 12. In the first and second exterior electric power terminals 18 and 20, mounting holes 22 and 24 are formed, respectively.

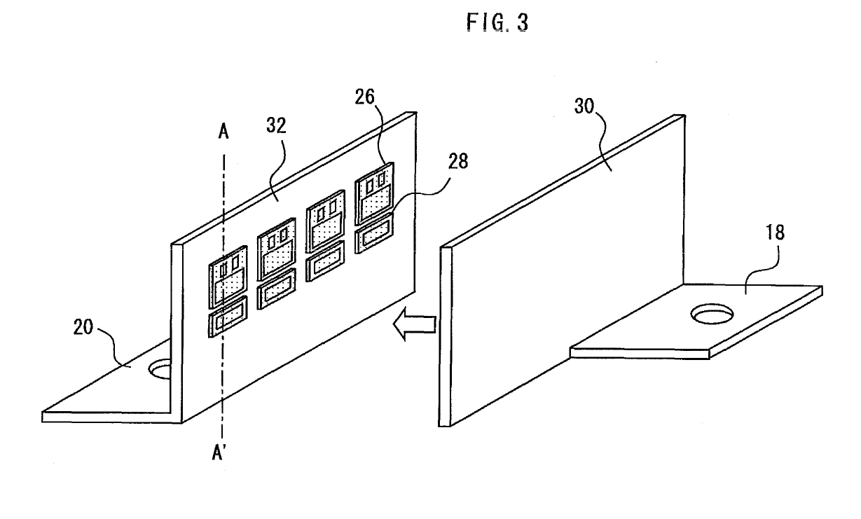

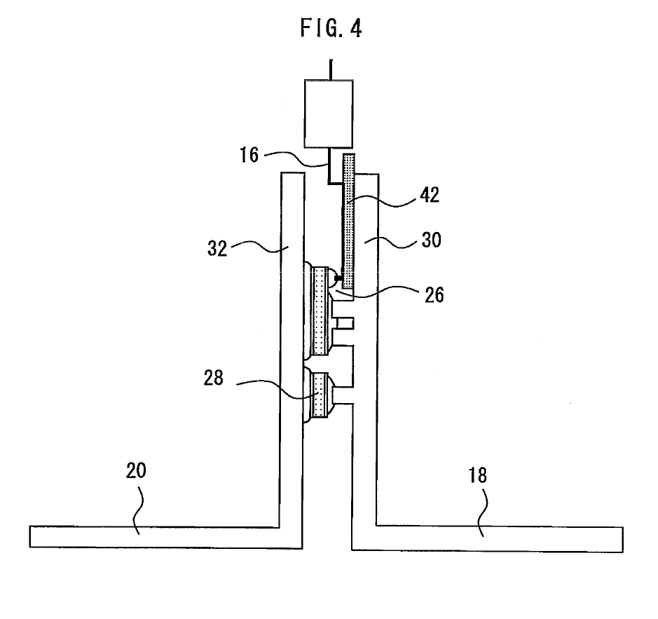

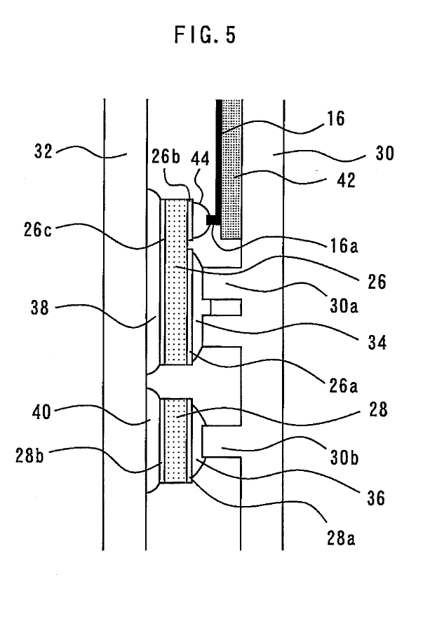

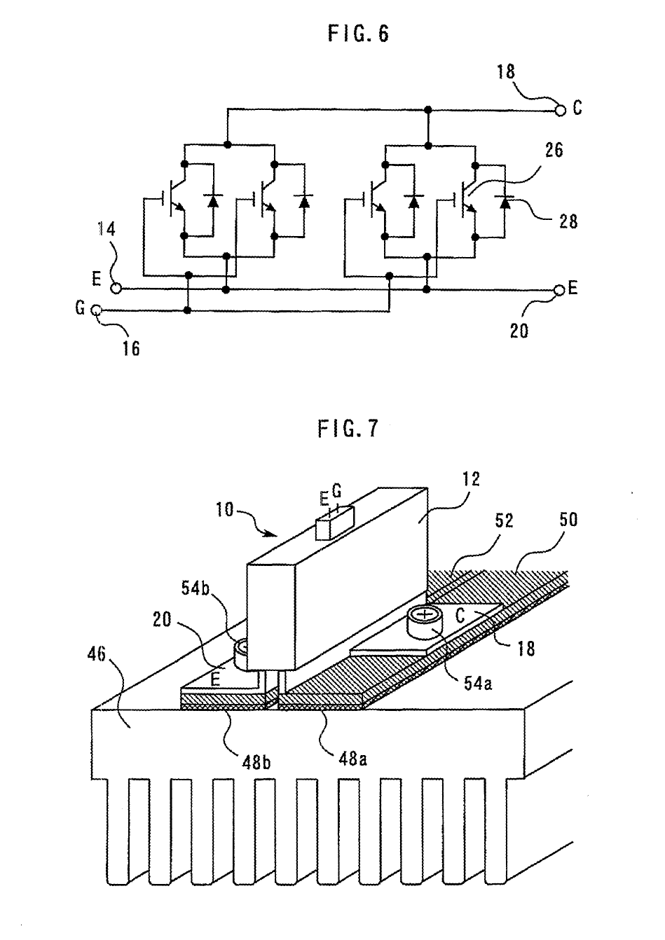

FIG. 3 is a perspective view showing the interior of the power semiconductor device shown in FIG. 1. FIG. 4 is a sectional view taken along the line A-A′ in FIG. 3. FIG. 5 is an enlarged sectional view showing the major parts of FIG. 4. FIG. 6 is a circuit diagram of the power semiconductor device shown in FIG. 1.

Four IGBT chips 26 and four free-wheel diode chips 28 are connected in parallel. An emitter 26a (first power terminal) and a gate 26b (signal terminal) are formed on the first major surface of each IGBT chip 26 (power chip), and a collector 26c (second power terminal) is formed on the second major surface facing the first major surface. An anode 28a is formed on the first major surface of each free-wheel diode chip 28, and a cathode 28b is formed on the second major surface.

A first metal plate 30 and a second metal plate 32 are arranged so as to face each other. A convex portion 30a of the first metal plate 30 is connected to the emitter 26a of the IGBT chip 26 by a solder 34, and a convex portion 30b of the first metal plate 30 is connected to the anode 28a of the free-wheel diode chip 28 by a solder 36. The second metal plate 32 is connected to the collector 26c of the IGBT chip 26 and the cathode 28b of the free-wheel diode chip 28 by solders 38 and 40, respectively. The exterior signal terminals 16 is isolated from the first metal plate 30 by an insulating plate 42; and the convex portion 16a of the exterior signal terminals 16 is connected to the gate 26b of the IGBT chip 26 by a solder 44.

The IGBT chip 26 is coated with the insulating cover 12 formed of resin from the outside of the first and second metal plates 30 and 32 to form the power semiconductor device 10 shown in FIG. 1. The first and second metal plates 30 and 32 have first and second exterior electric power terminals 18 and 20 derived from the lower surface of the insulating cover 12, respectively.

Since no wire bonding to the IGBT chip 26 is required in the above-described configuration, manufacturing becomes facilitated and the manufacturing costs can be lowered. In addition, since wiring from the IGBT chip 26 to the first and second exterior electric power terminals 18 and 20 becomes simple, and the first and second metal plates 30 and 32 flow electric current to a wide area, the resistance of internal wirings and self inductance can be lowered. Moreover, since the first and second metal plates 30 and 32 face one another, and flow electric current in the opposite direction, mutual inductance can also be lowered.

Moreover, by providing the convex portions 30a and 30b, the connection of the IGBT chip 26 and the free-wheel diode chip 28 to the first metal plate 30 is facilitated. Further, the tolerance to mechanical stress or thermal stress can be improved.

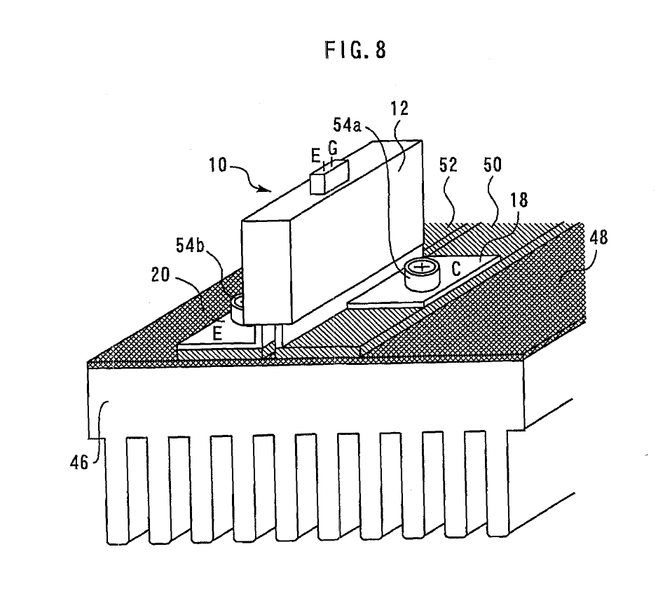

FIG. 7 is a perspective view showing an example of the state wherein the power semiconductor device shown in FIG. 1 is mounted on a heat sink. On the heat sink 46, which is a cooling member, exterior wirings 50 and 52, such as path bars, are mounted via insulating sheets 48a and 48b, respectively. By insulating screws 54a and 54b inserted in the mounting holes 22 and 24, respectively, the first and second exterior electric power terminals 18 and 20 are electrically connected to the external wirings 50 and 52, respectively, and fixed to the heat sink 46. An insulating sheet 48 may be disposed on the entire surface of the heat sink 46 as shown in FIG. 8.

Since the power semiconductor device 10 is vertically mounted to the upper surface of the heat sink 46 as described above, the mounting area is small. Since the exterior signal terminals 14 and 16 are extended from the opposite side to the first and second exterior electric power terminals 18 and 20 of the insulating cover 12, these can be easily connected to the exterior signal terminals 14 and 16.

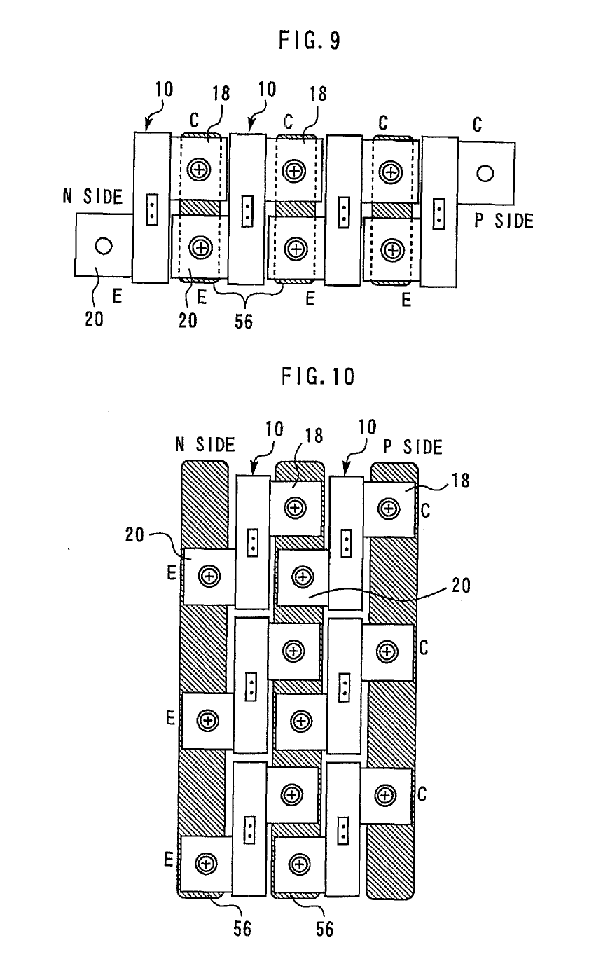

FIG. 9 is a plan view showing an example of the layout of the power semiconductor device shown in FIG. 1. Four power semiconductor devices 10 are connected in series via external wirings 56. FIG. 10 is a plan view showing another example of the layout of the power semiconductor device shown in FIG. 1. Two systems wherein three power semiconductor devices 10 are connected in parallel via external wirings 56, are connected is series. As described above, two power semiconductor devices 10 can be proximately positioned so that the first exterior electric power terminal 18 of one power semiconductor device 10 does not overlap the second exterior electric power terminal 20 of the other power semiconductor device 10. Therefore, the mounting area can be reduced especially in serial connection. Thereby, a small power system can be configured.

### SECOND EMBODIMENT

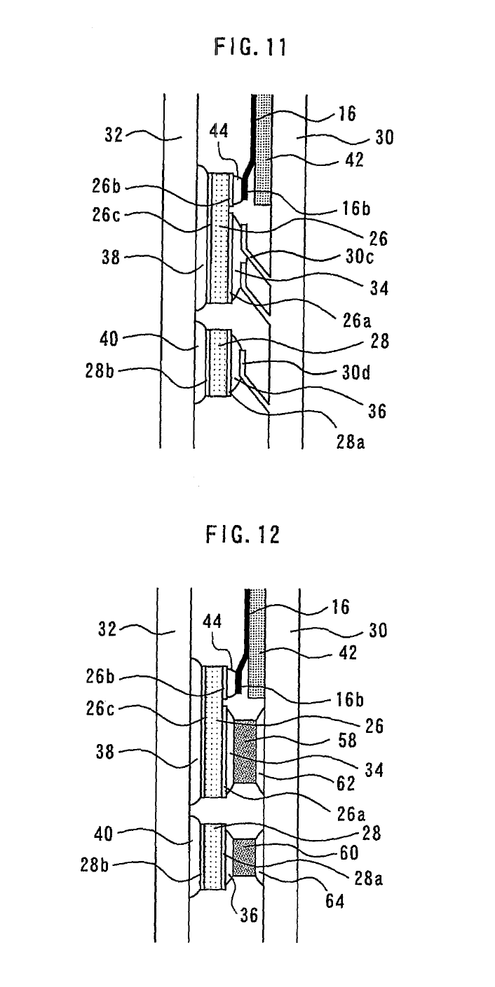

FIG. 11 is a sectional view showing the interior of a power semiconductor device according to the second embodiment of the present invention. An elastic portion 30c of the first metal plate 30 is connected to the emitter 26a of the IGBT chip 26 by a solder 34, and an elastic portion 30d of the first metal plate 30 is connected to the anode 28a of the free-wheel diode chip 28 by a solder 36. An elastic portion 16b of the exterior signal terminals 16 is connected to the gate 26b of the IGBT chip 26 by a solder 44. Other configurations are identical to the configurations in the first embodiment.

By providing the elastic portions 30c and 30d as described above, the connection of the IGBT chip 26 or the free-wheel diode chip 28 to the first metal plate 30 is facilitated. Further, the tolerance to mechanical stress or thermal stress can be improved.

### THIRD EMBODIMENT

FIG. 12 is a sectional view showing the interior of a power semiconductor device according to the third embodiment of the present invention. Stress-relaxing metal plates 58 and 60 are connected to the first metal plate 30 by solders 62 and 64, respectively. The first metal plate 30 is connected to the emitter 26a of the IGBT chip 26 via the stress-relaxing metal plate 58 by a solder 34, and is connected to the anode 28a of the free-wheel diode chip 28 via the stress-relaxing metal plate 60 by a solder 36. The stress-relaxing metal plates 58 and 60 are formed of a substance having a thermal expansion coefficient between the IGBT chip 26 or the free-wheel diode chip 28 and the first metal plate 30, such as Mo. Other configurations are identical to the configurations in the second embodiment.

Since the stress due to difference in thermal expansion coefficients between the IGBT chip 26 or the free-wheel diode chip 28 and the first metal plate 30 can be relaxed by inserting the stress-relaxing metal plates 58 and 60 between the IGBT chip 26 and the first metal plate :30 as described above, the tolerance to mechanical stress or thermal stress can be improved.

### FOURTH EMBODIMENT

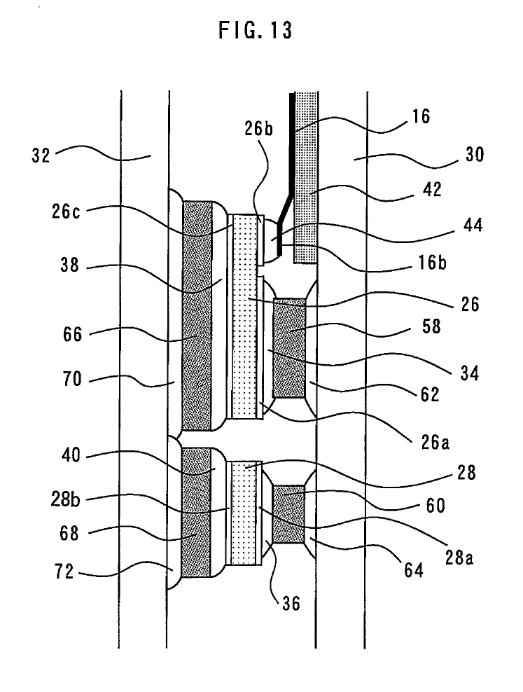

FIG. 13 is a sectional view showing the interior of a power semiconductor device according to the fourth embodiment of the present invention. Stress-relaxing metal plates 66 and 68 are connected to the second metal plate 32 by solders 70 and 72. The second metal plate 32 is connected to the collector 26c of the IGBT chip 26 via the stress-relaxing metal plate 66 by a solder 38, and is connected to the cathode 28b of the free-wheel diode chip 28 via the stress-relaxing metal plate 68 by a solder 40. The stress-relaxing metal plates 66 and 68 are formed of a substance having a thermal expansion coefficient between the IGBT chip 26 or the free-wheel diode chip 28 and the second metal plate 32, such as Mo. Other configurations are identical to the configurations in the third embodiment.

Since the stress due to difference in thermal expansion coefficients between the IGBT chip 26 or the free-wheel diode chip 28 and the second metal plate 32 can also be relaxed by inserting the stress-relaxing metal plates 66 and 68 between the IGBT chip 26 and the second metal plate 32 as described above, the tolerance to mechanical stress or thermal stress can be more improved than the third embodiment.

### FIFTH EMBODIMENT

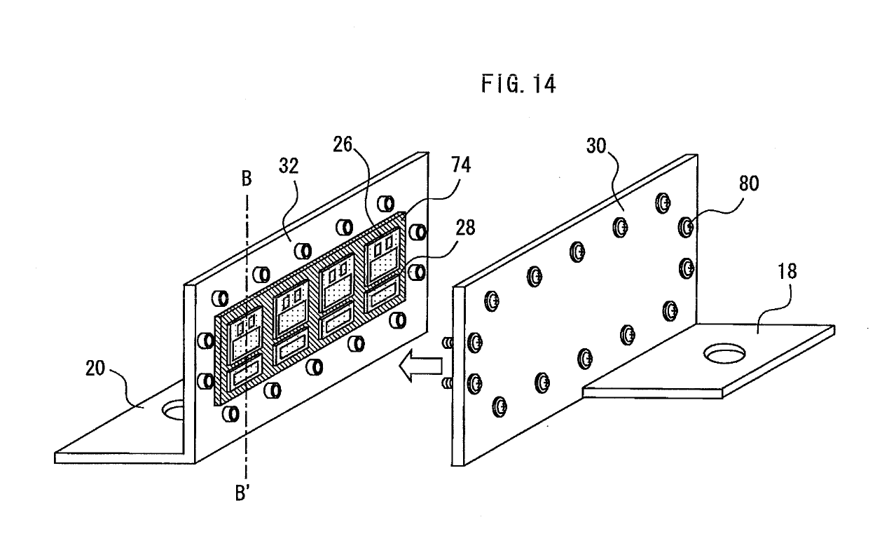

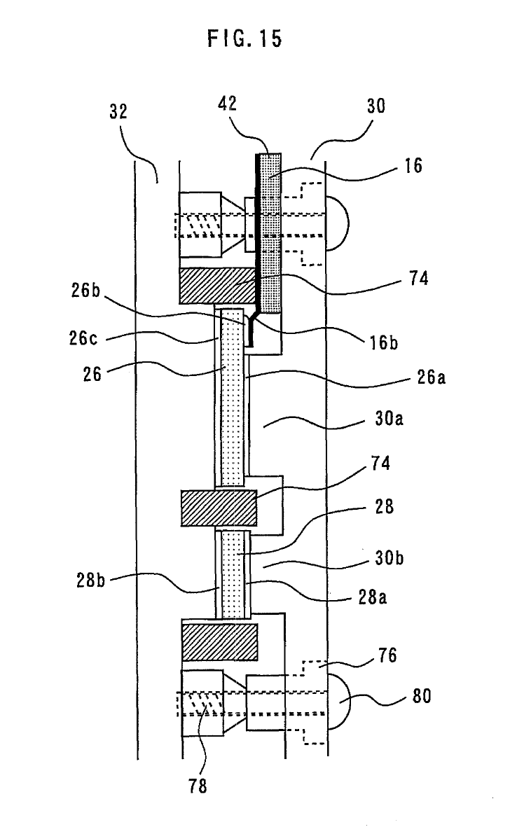

FIG. 14 is a sectional view showing the interior of a power semiconductor device according to the fifth embodiment of the present invention. FIG. 15 is a sectional view taken along the line B-B′ in FIG. 14.

An insulating guide 74 surrounding the IGBT chip 26 and the free-wheel diode chip 28 is disposed between the first metal plate 30 and the second metal plate 32. The first metal plate 30 and the second metal plate 32 are screwed by screws 80 via insulating bushes 76 and the springs 78. Thereby, the convex portion 30a of the first metal plate 30 is pressure-bonded to the emitter 26a of the IGBT chip 26, and the convex portion 30b of the first metal plate 30 is pressure-bonded to the anode 28a of the free-wheel diode chip 28. The second metal plate 32 is pressure-bonded to the collector 26c of the IGBT chip 26 and the cathode 28b of the free-wheel diode chip 28. The elastic portion 16b of the exterior signal terminals 16 is pressure-bonded to the gate 26b of the IGBT chip 26. Other configurations are identical to the configurations in the first embodiment.

Since the IGBT chip 26 and the free-wheel diode chip 28 are pressure-bonded to the first and second metal plates 30 and 32 without using solder or the like as described above, assembling is facilitated. Also since the misalignment of the IGBT chip 26 or the free-wheel diode chip 28 during pressure bonding can be prevented, a power semiconductor device with high reliability can be realized.

In the present embodiment, although pressure-bonded structure using screwing has been described, the present invention is not limited thereto, but other structures wherein the IGBT chip 26 or the free-wheel diode chip 28 is pressure-bonded to the first and second metal plates 30 and 32 can also be used.

### SIXTH EMBODIMENT

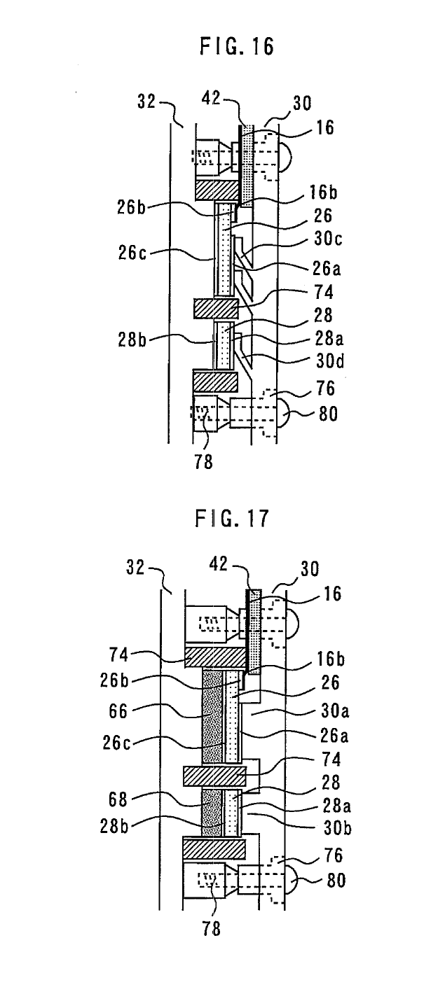

FIG. 16 is a sectional view showing the interior of a power semiconductor device according to the sixth embodiment of the present invention. The elastic portion 30c of the first metal plate 30 is pressure-bonded to the emitter 26a of the IGBT chip 26, and the elastic portion 30d of the first metal plate 30 is pressure-bonded to the anode 28a of the free-wheel diode chip 28. Other configurations are identical to the configurations in the fifth embodiment.

By providing the elastic portions 30c and 30d as described above, the connection of the IGBT chip 26 or the free-wheel diode chip 28 to the first metal plate 30 is facilitated. Further, the tolerance to mechanical stress or thermal stress can be improved.

### SEVENTH EMBODIMENT

FIG. 17 is a sectional view showing the interior of a power semiconductor device according to the seventh embodiment of the present invention. The second metal plate 32 is pressure-bonded to the collector 26c of the IGBT chip 26 via the stress-relaxing metal plate 66, and is pressure-bonded to the cathode 28b of the free-wheel diode chip 28 via the stress-relaxing metal plate 68. The stress-relaxing metal plates 66 and 68 are formed of a substance having a thermal expansion coefficient between the IGBT chip 26 or the free-wheel diode chip 28 and the second metal plate 32, such as Mo. To prevent misalignment during pressure bonding, the insulating guide 74 surrounds the stress-relaxing metal plates 66 and 68. Other configurations are identical to the configurations in the fifth embodiment.

Since the stress due to difference in thermal expansion coefficients between the IGBT chip 26 or the free-wheel diode chip 28 and the second metal plate 32 can be relaxed by inserting the stress-relaxing metal plates 66 and 68 between the IGBT chip 26 and the second metal plate 32 as described above, the tolerance to mechanical stress or thermal stress can be improved.

### EIGHTH EMBODIMENT

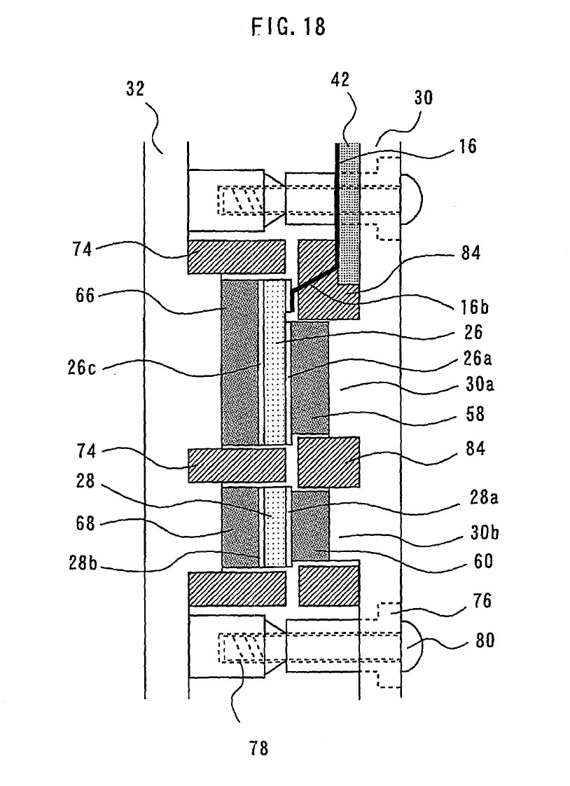

FIG. 18 is a sectional view showing the interior of a power semiconductor device according to the eighth embodiment of the present invention. The first metal plate 30 is pressure-bonded to the emitter 26a of the IGBT chip 26 via the stress-relaxing metal plate 58, and is pressure-bonded to the anode 28a of the free-wheel diode chip 28 via the stress-relaxing metal plate 60. The stress-relaxing metal plates 58 and 60 are formed of a substance having a thermal expansion coefficient between the IGBT chip 26 or the free-wheel diode chip 28 and the first metal plate 30, such as Mo. To prevent misalignment during pressure bonding, an insulating guide 84 surrounds the stress-relaxing metal plates 58 and 60. Other configurations are identical to the configurations in the seventh embodiment.

Since the stress due to difference in thermal expansion coefficients between the IGBT chip 26 or the free-wheel diode chip 28 and the first metal plate 30 can be relaxed by inserting the stress-relaxing metal plates 58 and 60 between the IGBT chip 26 and the first metal plate 30 as described above, the tolerance to mechanical stress or thermal stress can be more improved than the seventh embodiment.

1. A power semiconductor device comprising:
a power chip wherein a first power terminal and a signal terminal are formed on a first major surface and a second power terminal is formed on a second major surface facing the first major surface;
a first metal plate connected to the first power terminal of the power chip;
a second metal plate arranged so as to face the first metal plate and connected to the second power terminal of the power chip;
an insulating cover coating the power chip from outside of the first and second metal plates; and
an exterior signal terminal connected to the signal terminal of the power chip and derived from an upper surface of the insulating cover,
the first metal plate includes a first exterior electric power terminal derived from a lower surface of the insulating cover,
the second metal plate includes a second exterior electric power terminal derived from a lower surface of the insulating cover,
the first and second exterior electric power terminals are bent to opposite directions,
in a bending direction of the first exterior electric power terminal or the second exterior electric power terminal, the second exterior electric power terminal is not present on opposite side of the first exterior electric power terminal across the insulating cover, and the first exterior electric power terminal is not present on opposite side of the second exterior electric power terminal across the insulating cover.

2. The power semiconductor device according to claim 1, wherein the first metal plate includes a convex portion connected to the first power terminal of the power chip.

3. The power semiconductor device according to claim 1, wherein the first metal plate includes an elastic portion connected to the first power terminal of the power chip.

4. The power semiconductor device according to claim 1, further comprising a stress-relaxing metal plate inserted between the power chip and the first metal plate and/or between the power chip and the second metal plate,
wherein the stress-relaxing metal plate is formed of a substance having a thermal expansion coefficient between those of the power chip and the first and second metal plates.

5. The power semiconductor device according to claim 1, further comprising an insulating guide disposed between the first metal plate and the second metal plate and surrounding the power chip,
the first power terminal of the power chip is pressure-bonded to the first metal plate,
the second power terminal of the power chip is pressure-bonded to the second metal plate.

6. The power semiconductor device according to claim 5, wherein the first metal plate and the second metal plate are screwed across the power chip.
